(19) United States
(12) Patent Application Publication
(10) Pub. No.: US 2024/0290723 A1
(43) Pub. Date: Aug. 29, 2024

(54) PROTECTION AGAINST ELECTROMIGRATION WITHIN A LAYER OF AN INTEGRATED CIRCUIT

(71) Applicant: Intel Corporation, Santa Clara, CA (US)

(72) Inventors: Jason Gamba, Gilbert, AZ (US); Suddhasattwa Nad, Chandler, AZ (US); Sanjay Tharmarajah, Queen Creek, AZ (US); Rajeev Ranjan, Chandler, AZ (US); Greg Aponte, Maricopa, AZ (US)

(73) Assignee: Intel Corporation, Santa Clara, CA (US)

(21) Appl. No.: 18/114,120

(22) Filed: Feb. 24, 2023

(51) Int. Cl. H01L 23/538; H01L 21/768; H01L 23/532

(52) U.S. Cl. CPC H01L 23/5384; H01L 21/76834; H01L 21/76846; H01L 23/5329

(57) ABSTRACT

An apparatus comprises a first layer comprising a first dielectric material, and first and second regions on a first side of the first layer. The first regions comprise a first surface in a first plane, and each of the second regions comprise a second surface in a second plane spaced away from the first plane by a first distance. Sidewalls extend between the first surface and the second surfaces. The apparatus further comprises a plurality of conductive features, each conductive feature comprising a bottom surface on one of the second surfaces, and a barrier film comprising a second dielectric material that contacts the sidewalls.

### BACKGROUND

Current flow in conductors in integrated circuits (ICs) results in electric fields. These electric fields can cause material in the conductors to migrate. Material migration resulting from an electric field is referred to as electromigration. Over time, electromigration can cause metal to be depleted or accumulated in different areas of a conductive interconnect, such as, a trace, via, pad, or the like. An open circuit can occur if enough conductive material, e.g., copper, is depleted in a region of a conductive interconnect. A short circuit can occur if enough conductive material is accumulated in a region between two adjacent conductive interconnects. Accordingly, over time, electromigration can damage interconnects, which affects the reliability of an integrated circuit device.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. Certain figures may be shown in an idealized fashion in order to aid understanding, such as when structures are shown having straight lines, sharp angles, and/or parallel planes or the like that under real-world conditions would likely be significantly less symmetric and orderly. In the figures:

FIG. 1 illustrates a flow diagram of methods for fabricating an IC die that comprises elevated regions on a surface of a layer of the IC, conductive features on the elevated regions, and a barrier film on sidewalls of the elevated regions, in accordance with some embodiments;

FIG. 2A and FIG. 2B are, respectively, a cross-sectional illustration and a plan view of a first layer that may be a starting material of an IC die in accordance with some embodiments;

FIG. 3A and FIG. 3B are, respectively, a cross-sectional illustration and a plan view of the first layer of FIGS. 2A and 2B at a stage of manufacturing after a plurality of conductive features have been fabricated on a first surface of the first layer, in accordance with some embodiments;

FIG. 4A and FIG. 4B are, respectively a cross-sectional illustration of the IC die of FIGS. 2A-2B and 3A-3B at a stage of manufacturing after an etch process has been completed, according to some embodiments;

FIG. 5 shows an example of removal of silica and epoxy from an opening in a dielectric material using a dry plasma etch, according to some embodiments;

FIG. 6 shows examples of using a dry plasma etch to tune surface roughness, according to some embodiments;

FIG. 7 is a cross-sectional illustration of the IC die of FIGS. 2A-2B, 3A-3B, and 4A-4B at a stage of manufacturing after a barrier film has been formed, according to some embodiments;

FIG. 8 is a cross-sectional illustration of an IC die of FIGS. 2A-2B, 3A-3B, 4A-4B and 7 at a stage of manufacturing after a third dielectric material has been formed over a barrier film, according to some embodiments;

FIG. 9 is a cross-sectional, enlarged illustration of an area of an IC die of FIG. 8, according to some embodiments;

FIG. 10 is a cross-sectional illustration of an IC die at a stage of manufacturing after multiple layers have been formed, according to some embodiments;

FIG. 11 is a functional block diagram of an electronic computing device, in accordance with some embodiments; and

FIG. 12 illustrates a mobile computing platform and a data server machine employing a composite IC chip structure, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or functional changes may be made without departing from the scope of claimed subject matter. It should also be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with each of the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

ICs described herein may include logic, memory, or other any other type of known circuitry. In some embodiments, an IC may comprise any type of semiconductor device. In one embodiment, the IC comprises a processing system or device. For example, an IC may comprise a microprocessor or a graphics processor. The IC can perform instructions from any number of processor architectures having any number of instruction formats. In one embodiment, the IC may employ an “x86” instruction set architecture, as used by Intel Corporation. However, in other embodiments, the processor may perform instructions from other architectures or from other processor designers. For example, in some embodiments, the IC may employ a reduced instruction set computer (RISC) architecture. In another embodiment, the IC comprises a memory device. According to a further embodiment, the IC comprises a system-on-chip (SoC). In yet another embodiment, the IC may include digital circuitry, analog circuitry, or a combination of both analog and digital circuitry.

Embodiments are directed to an IC die that comprises elevated regions on a surface of a layer of the die, conductive features on the elevated regions, and a barrier film on sidewalls of the elevated regions. The example IC dies described herein comprise at least one metal layer on a dielectric layer. Some examples comprise multiple metal layers, each on a respective dielectric layer.

The term “metallization” generally refers to metal layers formed over and through a dielectric material of a package substrate. The metal layers are generally patterned to form metal structures such as traces and bond pads. The metallization of a package substrate may be confined to a single layer or may be provided in multiple layers separated by layers of dielectric. A dielectric layer may comprise any suitable dielectric material (e.g., polymer materials, silicon dioxide (Si02), silicon nitride (Si3N4), etc.) and may be formed by any suitable technique (e.g., by deposition, lamination, plasma-enhanced chemical vapor deposition (PECVD), etc.) In some embodiments, a dielectric material may be dielectric/organic materials, resins, epoxies, polymer adhesives, silicones, acrylics, polyimides, cyanate esters, thermoplastics, and/or thermosets. A metallization layer may comprise any suitable electrically conductive metal (e.g., copper, aluminum, silver, etc.), and may be deposited by any suitable technique (e.g., plating processes, such as electroplating and electroless plating). Further, a metal layer may be patterned to form any suitable number and configuration of traces, power planes, ground planes, and other conductors to facilitate the routing of power and I/O signals. In embodiments, a layer may be coupled with a power supply, e.g., a power plane or other power conductor in a metallization layer may be coupled with a power supply. In some embodiments, an IC die may include a redistribution layer.

Depending on its composition, the surface roughness of a dielectric layer will have some roughness value. Surface roughness may be described with a surface roughness parameter, such as the average deviation from a plane parallel with the layer. One example parameter is average surface roughness (Ra). Presently, there is trend in semiconductor manufacturing toward the use of dielectrics with lower surface roughness values than have been used in the past. As described below, aspects of some embodiments provide for tuning the surface roughness in a particular region of a surface of a dielectric layer to help protect against electromigration between conductive features.

When a layer is formed on another layer or a metallization feature, it is important that the layer have good adherence to the layer or feature it is formed on. For example, it is important that a material in a metallization layer adhere to the dielectric layer or metallization feature it is formed on. Failure of the material to adhere to a dielectric layer or metallization feature can result in delamination, which can lead to a catastrophic failure. In embodiments, silicon nitride (SiNx) is used in semiconductor manufacturing as adhesion promoter for dielectrics with low surface roughness. In addition, in embodiments, silicon nitride is used as an electromigration barrier layer.

The examples presented herein are for only some of the layers in an integrated circuit. Some examples describe an apparatus comprising a single metal layer on a dielectric layer, while other examples describe an apparatus comprising two metal layers, each on a dielectric layer. However, it should be appreciated that the structures and features described herein for single or plural metal layers can be provided in any layer of a multi-layer integrated circuit. For example, the structures and features could be in a top-most layer, a bottom layer, or any layer in between. Moreover, the structures and features described herein for a single metal layer can be provided in more than one layer of an integrated circuit. In some embodiments, the structures and features described herein for a single layer are provided in every metallization layer in an IC. In addition, it should also be appreciated that the structures and features described herein may be fabricated in wafer level or substrate level processes.

In some embodiments, a first layer of an IC or other apparatus has a first side. The first layer comprises a first dielectric material, and the first side has first and second regions. The first regions are in a first plane. Each of the second regions are elevated with respect to the first plane. In particular, each of the second regions comprise a second surface in a second plane that is spaced away from or above the first plane by a first distance. Each of the second, elevated regions have one or more sidewalls extending between the first surface and the second surface. The first distance may be height of the sidewalls.

In some embodiments, conductive features are on the second surfaces. Each conductive feature is part of a metallization layer, and comprises a bottom surface and an opposite top surface. The bottom surface is in contact with one of the second surfaces of the second regions. Each of the conductive features comprises one or more conductive feature sidewall extending between the bottom surface and the top surface of the conductive feature. The first regions may be formed by any suitable process that does not damage to conductive features formed on the second surfaces. In an embodiment, the first regions may be formed by using the second regions as a mask in a mask-and-etch process.

In some embodiments, a barrier film contacts the sidewalls extending between the first surface and the second surface. The barrier film may also contact the first surface in first regions. In addition, the barrier film may contact conductive feature sidewalls extending between the bottom surface and the top surface of the conductive feature. Further, the barrier film may contact the top surfaces of the conductive features. The barrier film comprises a second dielectric material, which in some embodiments, is silicon nitride (SiNx). In other embodiments, the second dielectric material may comprise silicon oxynitride, silicon oxide, or a carbon doped oxide.

An advantage of the example integrated circuits described herein is that the sidewalls of the elevated, second regions and the portions of the barrier film contacting their sidewalls protect against intralayer electromigration. As explained below, this protection is achieved by making the path for an electromigration process between adjacent conductive features on the second regions longer. In particular, elevating the second regions and providing a barrier film on the sidewalls of the second regions makes the electromigration path between adjacent conductive features longer. These features also alter the direction of part of the path material would need to migrate such that the material would need to move in a direction not aligned with the electric field driving the process. In addition, an etch process may selectively increases the surface roughness of the first regions of the first surface between adjacent conductive features to add length to a possible path of electromigration. As a result, the structures and features described herein may lengthen the time period before electromigration failure occurs or may prevent electromigration failure altogether. As such, a further advantage of the integrated circuits described herein is that product lifetime may be extended.

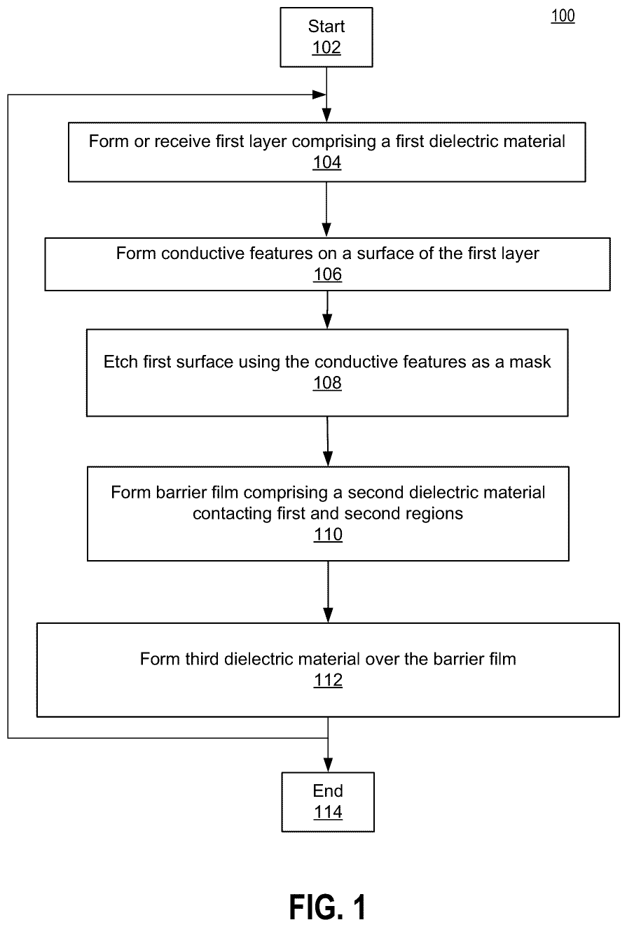

A number of different assembly and/or fabrication methods may be practiced to generate an IC die having one or more of the features or attributes described herein. FIG. 1 illustrates a flow diagram of methods 100 for fabricating an IC die that comprises elevated regions on a surface of a layer of the IC die, conductive features on the elevated regions, and a barrier film on sidewalls of the elevated regions, in accordance with some embodiments. Methods 100 begin at block 102. Methods 100 are described with respect to a substrate, but may also be performed on a wafer package.

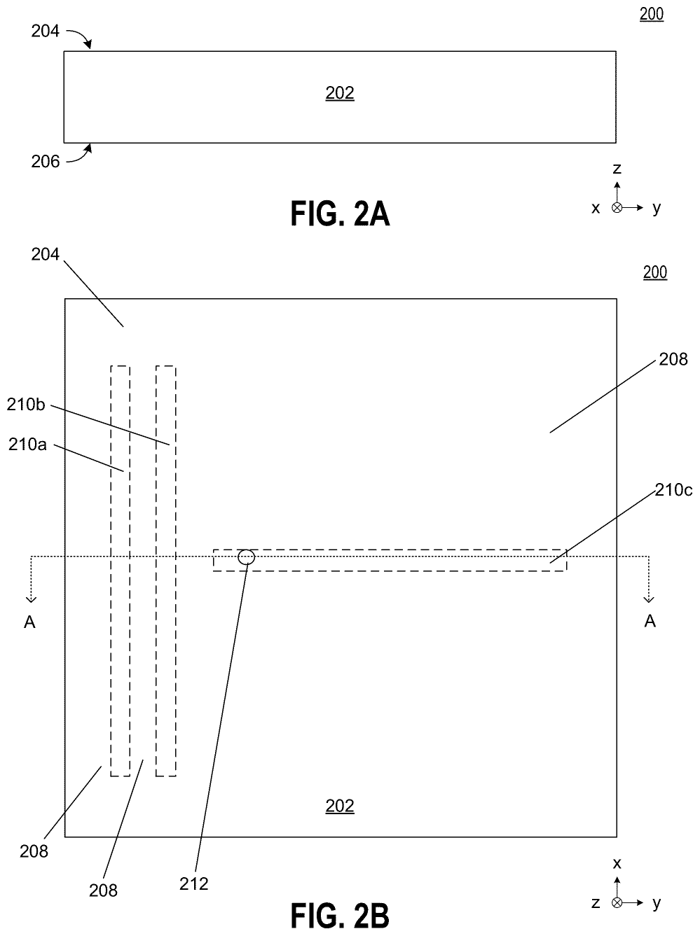

At 104, a first layer is formed or received as a starting material, in accordance with some embodiments. FIG. 2A is a cross-sectional illustration of a first layer 202 that may be formed or received as a starting material of IC die 200. In some embodiments, first layer 202 is an IC die substrate. In some embodiments, first layer 202 is a wafer. In some embodiments, first layer 202 is disposed on another layer of the IC die 200. FIG. 2B is a plan view of the first layer 200. FIG. 2A is a cross-section taken along a line A-A. To simplify the illustrations herein, the first layer 200 shown in FIGS. 2A and 2B is sized for a single IC die. It should be appreciated, however, that first layer 200 may be of sufficient size to fabricate multiple IC dies simultaneously. Accordingly, the methods 100 can include a singulation step (not shown).

The first layer 202 comprises a first dielectric material, which may be any suitable dielectric material. For example, first layer 202 may comprise composite polymer/filler material, or other dielectric/organic materials, resins, epoxies, polymer adhesives, silicones, acrylics, polyimides, cyanate esters, thermoplastics, and/or thermosets. In some embodiments, first layer 202 comprises a dielectric material containing a filler, such as an epoxy with a silica filler. In some embodiments, first layer 202 comprises a filler-less dielectric, which may provide a low-roughness surface subsequent to a dry plasma etch described below, without crater formation resulting from filler removal. The first layer 202 may be formed by any suitable technique (e.g., by deposition, lamination, plasma-enhanced chemical vapor deposition (PECVD), etc.). The first layer 202 comprises an upper surface 204 and an opposite lower surface 206. As can be seen in FIG. 2B, the upper surface 204 comprises first regions 208 and second regions 210 (specifically, second regions 210a, 210b, and 210c). The upper surface 204 may also include one or more via openings 212.

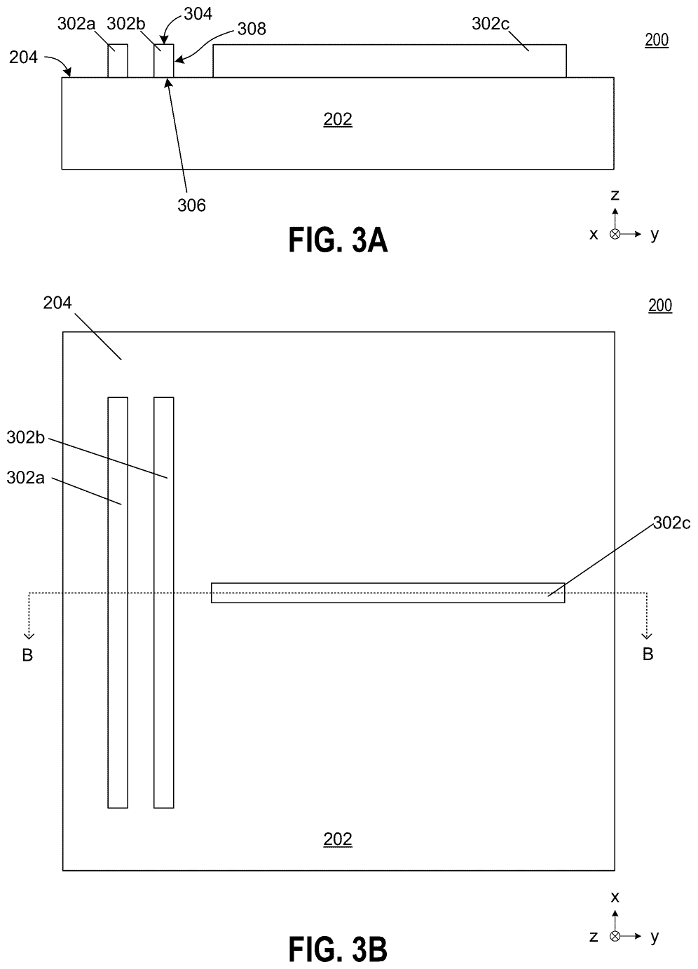

Returning to FIG. 1, at block 106 one or more conductive features are fabricated on upper surface 204 of first layer 202 of IC die 200, in accordance with some embodiments. FIG. 3A is a cross-sectional illustration of a first layer 202 at a stage of manufacturing after a plurality of conductive features have been fabricated on the upper surface 204 of first layer 200, according to some embodiments. FIG. 3B is a plan view of the first layer 202 at the stage of manufacturing shown in FIG. 3A. FIG. 3A is a cross-section taken along a line B-B.

Conductive features 302 on upper surface 204 are shown in the example depicted in FIGS. 3A and 3B. In embodiments, each conductive feature for which electromigration protection is desired is formed in one of the second regions 210. In the example of FIGS. 3A and 3B, conductive features 302a, 302b, and 302c are formed in locations respectively coinciding with second regions 210a, 210b, and 210c. In embodiments, the conductive features may be traces, pads, vias, or other electrically conductive structures or metallization features. In the shown example, conductive features 302a, 302b, and 302c are traces. The conductive features may have any composition and dimension suitable for routing electrical signals within first layer 202. The conductive features may be entirely with the first layer or may contact features in an adjacent layer, e.g., with a via. The conductive features may comprise any suitable electrically conductive metal (e.g., copper, aluminum, silver, etc.), and may be deposited by any suitable technique (e.g., plating processes, such as electroplating and electroless plating). In some embodiments, the conductive features may be comprised predominantly of copper. Each of the conductive features 302a, 302b, and 302c comprise a top surface 304 opposite a bottom surface 306. Sidewalls 308 extend between the top surface 304 and bottom surface 306 of the conductive features.

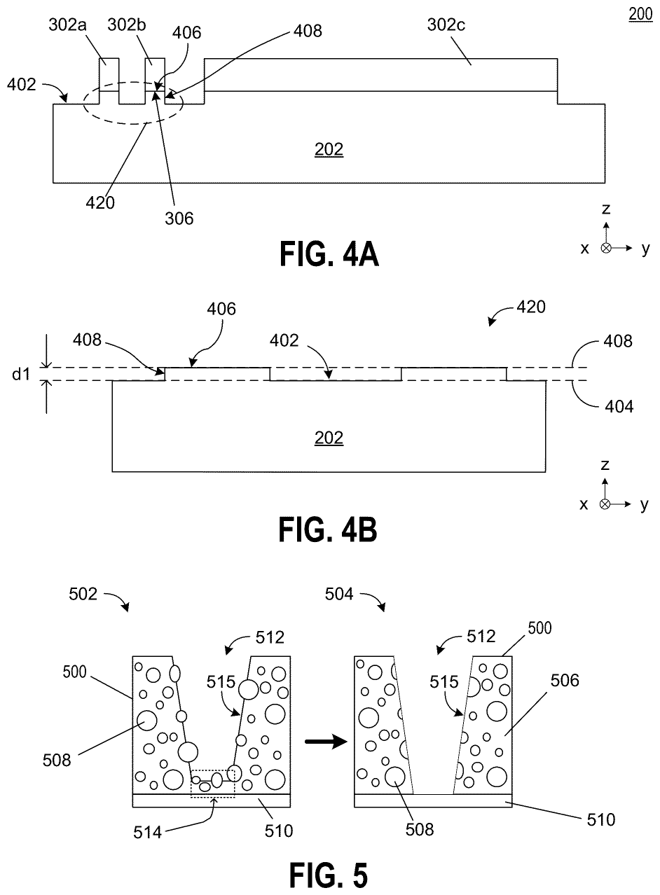

Referring to FIG. 1, at block 108 the upper surface of the first layer is etched using the conductive features as a mask to define first surfaces in the first regions in a first plane, in accordance with some embodiments. FIG. 4A is a cross-sectional illustration of an IC die 200 at a stage of manufacturing after the etch process to define first surfaces 402 in the first regions 208 in a first plane has been completed, according to some embodiments. An area 420 of IC die 200 is circled in FIG. 4A. FIG. 4B is a cross-sectional, enlarged illustration of the area 420 of IC die 200, which, for clarity, omits conductive features 302a and 302b. FIG. 4B is provided to clearly present the first layer of the example IC die 200. As can be seen in FIG. 4B, first surfaces 402 are in a first plane 404. The first plane 404 is an (x, y) plane. As a result of the second regions 210a, 210b, and 210c being masked during the etch process by conductive features 302a, 302b, and 302c, second surfaces 406, distinct from first surfaces 402, are defined. The second surfaces 406 are in the second regions 210a, 210b, and 210c, and in a second plane 408. The second plane 408 is an (x, y) plane, which may be parallel to the first plane 404. In some embodiments, the second plane 408 may be the same as or correspond with a plane in which the upper surface 204 lies (see FIG. 2A). As may be seen in FIG. 4A, the second surfaces 406 are in contact with bottom surfaces 306 of the conductive features 302.

Referring to FIG. 4B, the second plane is spaced away from the first plane by a first distance d1. As the second surfaces 406 are in the second plane, the second surfaces are also spaced away from the first plane by the first distance d1. The second regions comprise sidewalls 408 that extend between the first surface 402 to the second surface 406. In embodiments, the height of sidewalls 408 is the first distance d1. The first distance d1 may be any desired distance, provided it is less than the thickness of the first layer 202 and a thickness of a barrier film applied in a subsequent step. As one example, the first layer 202 may have a thickness of 40 microns and the distance d1 may be in a range of 25 nanometers to 5 or 10 microns.

In some embodiments, the first layer is etched using a dry plasma etch, which may also be referred to as a dry desmear etch. The plasma etch may be anisotropic. At 108, the plasma etch removes dielectric material from the first layer in first region(s) 208, but does not remove dielectric material under the conductive features 302 in second region(s) 210. In embodiments, a plasma etch is selected which does not cause appreciable undercut. In a known process, when holes are created in a dielectric material by laser drilling, e.g., for vias, debris can be left in the holes. A dry plasma etch may be used to remove debris from the holes. One of ordinary skill in the art will appreciate that the dry plasma etch employed at 108 may be the same as or similar to the etch that is known for removing debris from laser-drilled holes in a dielectric material. In some embodiments, the substrate or panel is placed in a plasma environment where the dielectric surface is bombarded with radicals and other species that will react with (breakdown) surface material, e.g., dielectric material, filler, and debris. The plasma may include argon, nitrogen, or other fluoridated species, and may be capacitively coupled with the first layer 202. The plasma environment converts material into species that can be carried away in a vapor phase. While the first layer 202 may be etched using a dry plasma etch in some embodiments, any other suitable process that removes dielectric material from the first layer in first region(s) 208, but does not remove dielectric material under the conductive features 302 in second region(s) 210 may be employed at block 108. For example, a reactive ion etch may be used at 108. In some embodiments, an ultrasound rinse is applied to clean the loose fillers (similar to post dry desmear to clean vias).

The filler removal rate of the dry plasma etch can be tuned with various parameters, gas flow, amount of fluorine present, power, etc. The filler removal rate is directly correlated to surface roughness. Accordingly, depending on parameter selection for filler removal rate, the first surfaces 402 in the first regions 208 may be formed with a desired surface roughness. In some embodiments, a barrier film is applied to first surfaces 402 in a step subsequent to 108. In some embodiments, the surface roughness of the first surfaces 402 is controlled to match the thickness of the barrier film. The surface roughness of the first surfaces 402 may be different from the surface roughness of the second surfaces 406, which may not be subject to an etch process. In some embodiments, the first surface 402 has a first surface roughness value, the second surface 406 has a second surface roughness value, and the first surface roughness value is greater than the second surface roughness value.

FIG. 5 shows a before-and-after example of removal of silica and epoxy from an opening in a dielectric material using a dry plasma etch, according to various embodiments. Dielectric material 500 comprises an epoxy 506 and a filler 508. The filler 508 may comprise particles of silica. In some embodiments, first layer 202 comprises the dielectric material 500. The dielectric material 500 is on metallization 510, which may be copper in this example. At stage 502, before a dry plasma etch, an opening 512 contains smear 514 at its bottom and some of the silica particles 508 protrude from sidewalls 515 of the opening 512. At subsequent stage 504, after a dry plasma etch, smear 514 is removed without causing damage to the metallization 510 and sidewalls 515 of the opening 512 are smoothed, such that the silica particles 508 no longer protrude from sidewalls 515. Embodiments of block 108 may employ any etch process that provides results similar to or the same as those shown in FIG. 5.

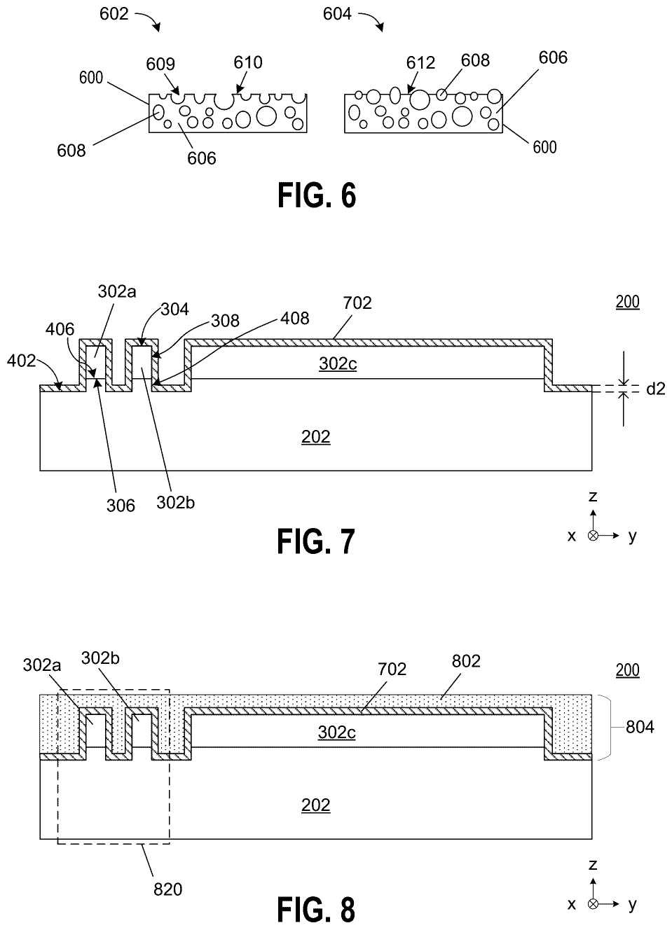

FIG. 6 shows examples of using a dry plasma etch to tune surface roughness, according to some embodiments. The examples show how the dry plasma etch process can be adjusted to affect filler versus epoxy removal in a dielectric material, which correlates to the depth of the etch and the resulting surface roughness. The two examples in FIG. 6 include dielectric material 600, which may be the same as the dielectric material 500 depicted in FIG. 5. The dielectric material 600 comprises epoxy 606 and a filler 608, which may be silica particles. Examples 602 and 604 may be in a layer or a region of a layer of an IC die. In example 602, a dry plasma etch removes more filler 608 than epoxy 606, providing the surface 610 with a first roughness value. In example 602, the surface 610 includes voids 609 where filler particles have been removed. In example 604, a dry plasma etch removes more epoxy 606 than filler 608, providing a surface 612 with a second roughness value. In example 604, it can be seen that the surface 612 includes filler particles 608 that protrude from the surface. In another example (not shown), the dry plasma etch removes equal amounts of epoxy 606 and filler 608, providing a surface with a third roughness value.

Referring to FIG. 1, at block 110 a barrier film comprising a second dielectric material contacting the first and second regions is formed, in accordance with some embodiments. FIG. 7 is a cross-sectional illustration of an IC die 200 at a stage of manufacturing after a barrier film 702 has been formed, according to some embodiments. As may be seen in FIG. 7, the barrier film 702 may be formed on all of first layer 202, except the second surface 406. In particular, barrier film 702 is formed on and contacts first surface 402 in the first region(s) 208 and the conductive features 302a, 302b, and 302c in the second regions 210. Inn embodiments, the barrier film 702 contacts the sidewalls 308 of the conductive features 302 that extend between the top surface 304 and bottom surface 306 of the conductive features. In addition, the barrier film 702 contacts the sidewalls 408 of each of the second regions 210 that extend from the first surface 402 to the second surface 406. The barrier film has a thickness d2. In some embodiments, the thickness d2 is equal to the first distance d1, e.g. the length of sidewalls 408. In some embodiments, the thickness d2 is less than the first distance d1, as shown in the example in FIG. 7. In some embodiments, the thickness d2 of the barrier film 702 does not exceed the dielectric roughness of first surface 402 in the first region(s) 208 of the first layer 202.

In embodiments, the barrier film 702 comprises a second dielectric material. In some embodiments, barrier film 702 comprises silicon nitride (SiNx). In some embodiments, barrier film 702 comprises one or more of: silicon nitride, silicon oxynitride, silicon oxide, and carbon doped oxides (CDO). In an embodiment, the second dielectric material is formed in a deposition process. In some embodiments, the barrier film 702 may be formed by any suitable technique (e.g., lamination, plasma-enhanced chemical vapor deposition (PECVD), etc.).

Referring to FIG. 1, at block 112 a third dielectric material is formed over the barrier film, according to some embodiments. FIG. 8 is a cross-sectional illustration of an IC die 200 at a stage of manufacturing after the third dielectric material 802 is formed over the barrier film 702, according to some embodiments. In some embodiments, formation of a third dielectric material over the barrier film may complete a second layer 804. In embodiments, the third dielectric material may be any suitable dielectric material. For example, third dielectric material 802 may comprise composite polymer/filler material, or other dielectric/organic materials, resins, epoxies, polymer adhesives, silicones, acrylics, polyimides, cyanate esters, thermoplastics, and/or thermosets. In various embodiments, the third dielectric material 802 may be the same as or different from the first dielectric material 202. In embodiments, the third dielectric material 802 is different from the barrier film 702. The third dielectric material 802 may be formed by any suitable technique (e.g., by deposition, lamination, plasma-enhanced chemical vapor deposition (PECVD), etc.).

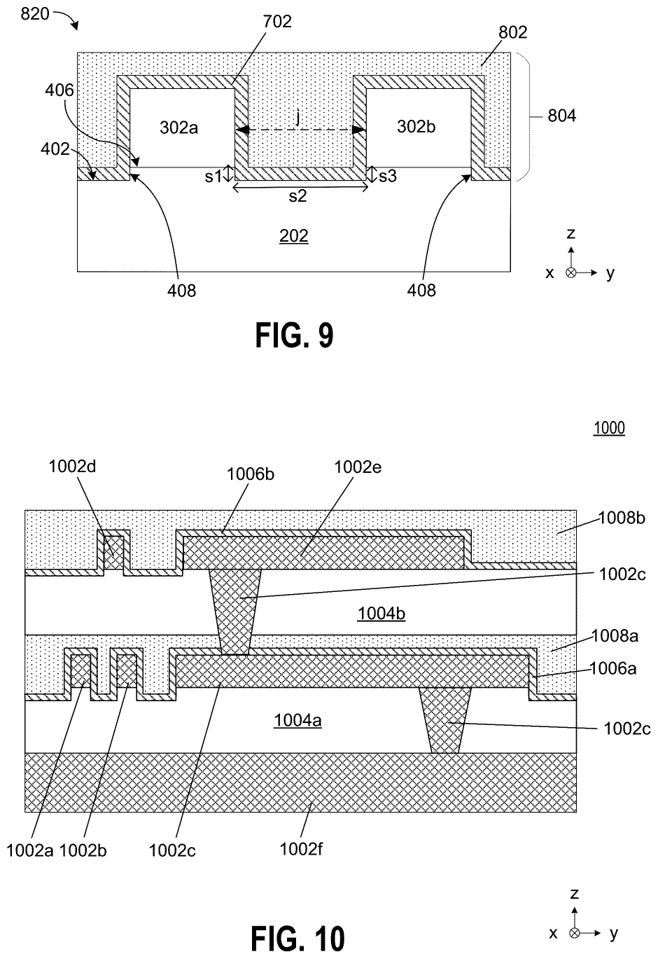

In FIG. 8, an area 820 of IC die 200 is enclosed in a dashed rectangle. FIG. 9 is a cross-sectional, enlarged illustration of the area 820 of IC die 200. FIG. 9 is provided to illustrate how the embodiments described herein make the path for an electromigration process between adjacent conductive features longer. Because electromigration along line j between conductive features 302a and 302b is prevented by barrier film 702 on the sidewalls of the respective conductive features 302a and 302b, electromigration, if it is to occur, would likely follow a path that avoid the sidewalls. For example, if first surface 402 and second surface 406 were in the same plane, electromigration would likely follow a path between conductive features 302a and 302b at or near an interface between first layer 202 and the third dielectric material 802 (or the interface between first layer 202 and a barrier film 702 on the first surface 402 between conductive features 302a and 302b). An advantage of embodiments described herein is that electromigration, if it is to occur, must follow a path defined by segments s1, s2, and s3. As can be seen in FIG. 9, elevating the second surfaces 406 with respect to the first surfaces 402, and providing a barrier film on the sidewalls 408 of the second regions, extends the path length by the sum of segments s1 and s3. Moreover, the direction that electromigration would need to take along segments s1 and s3 is not aligned with the electric field driving the electromigration process, which further reduces the likelihood of electromigration between conductive features. In addition, the disclosed dry plasma etch, or another suitable process, that selectively increases the surface roughness the first surface 402 of the first layer 202 along segment s2 adds multiple small “ups and downs” (see FIG. 6 for example) to the path. These small “ups and downs” at the surface increase the effective length of the electromigration path in comparison to a path on a smooth surface.

Referring to FIG. 1, after block 112, operations 104 to 112 may be repeated one or more times, or the methods may end at block 114, according to some embodiments. FIG. 10 is a cross-sectional illustration of an IC die 1000 at a stage of manufacturing after operations of methods 100 have been repeated one or more times, according to some embodiments.

As shown in FIG. 10, IC die 1000 comprises intra-layer conductive features (metallization features) 1002a, 1002b, 1002c, 1002d, 1002e, and 1002f. IC die 1000 comprises dielectric layers 1004a and 1004b, which are similar to first layer 202. Conductive features 1002a, 1002b, and 1002c are formed on a first surface of dielectric layer 1004a. Barrier film 1006a is formed on dielectric layer 1004a and conductive features 1002a, 1002b, and 1002c according to the methods 100. Conductive features 1002d and 1002e are formed on dielectric layer 1004b. Barrier film 1006b is formed on dielectric layer 1004b and conductive features 1002d and 1002e according to the methods 100. A dielectric material 1008a is formed on barrier film 1006a. Similarly, a dielectric material 1008b is formed on barrier film 1006b.

Upon completing the fabrication of an IC die, the IC die may be packaged and/or interconnected to any host component to which any IC package or monolithic IC chip may be attached. The IC die may be connected to a host component or other device. The IC die may be connected to a power supply.

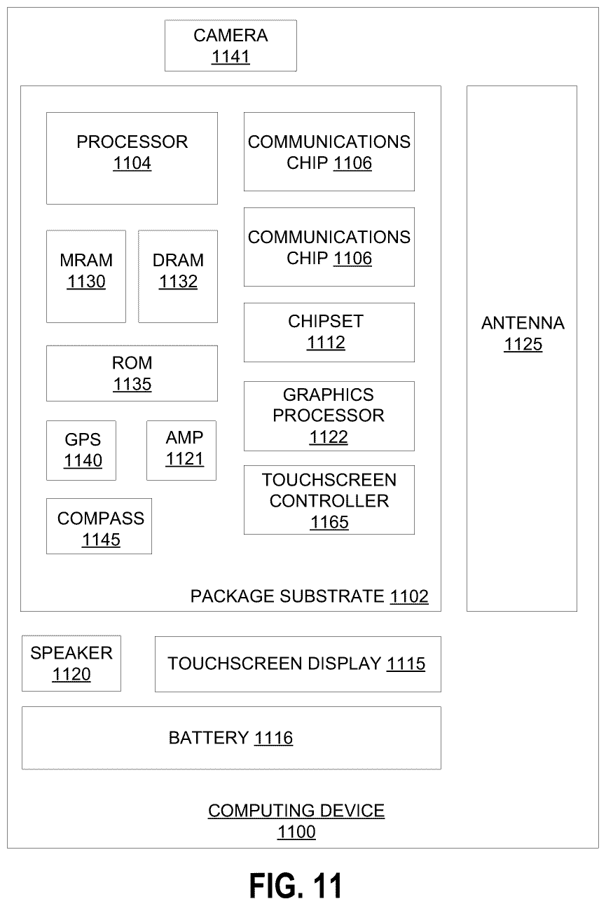

FIG. 11 is a functional block diagram of an electronic computing device 1100, in accordance with an embodiment of the present invention. Device 1100 further includes a package substrate 1102 hosting a number of components, such as, but not limited to, a processor 1104 (e.g., an applications processor). Processor 1104 may be physically and/or electrically coupled to package substrate 1102. In some examples, processor 1104 is within an IC die that comprises elevated regions on a surface of a layer of the IC, conductive features on the elevated regions, and a barrier film on sidewalls of the elevated regions, for example as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1106 may also be physically and/or electrically coupled to the package substrate 1102. In further implementations, communication chips 1106 may be part of processor 1104. Depending on its applications, computing device 1100 may include other components that may or may not be physically and electrically coupled to package substrate 1102. These other components include, but are not limited to, volatile memory (e.g., DRAM 1132), non-volatile memory (e.g., ROM 1135), flash memory (e.g., NAND or NOR), magnetic memory (MRAM 1130), a graphics processor 1122, a digital signal processor, a crypto processor, a chipset 1112, an antenna 1125, touchscreen display 1115, touchscreen controller 1165, battery 1116, audio codec, video codec, power amplifier 1121, global positioning system (GPS) device 1140, compass 1145, accelerometer, gyroscope, speaker 1120, camera 1141, and mass storage device (such as hard disk drive, solid-state drive (SSD), compact disk (CD), digital versatile disk (DVD), and so forth), or the like. In some exemplary embodiments, at two of the functional blocks noted above are within a composite IC chip structure including a chiplet bonded to a host IC chip, for example as described elsewhere herein. For example, processor 1104 may be implemented within circuitry in a first IC die, and an electronic memory (e.g., MRAM 1130 or DRAM 1132) may be implemented with circuitry in a second IC die.

Communication chips 1106 may enable wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1106 may implement any of a number of wireless standards or protocols. As discussed, computing device 1100 may include a plurality of communication chips 1106. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

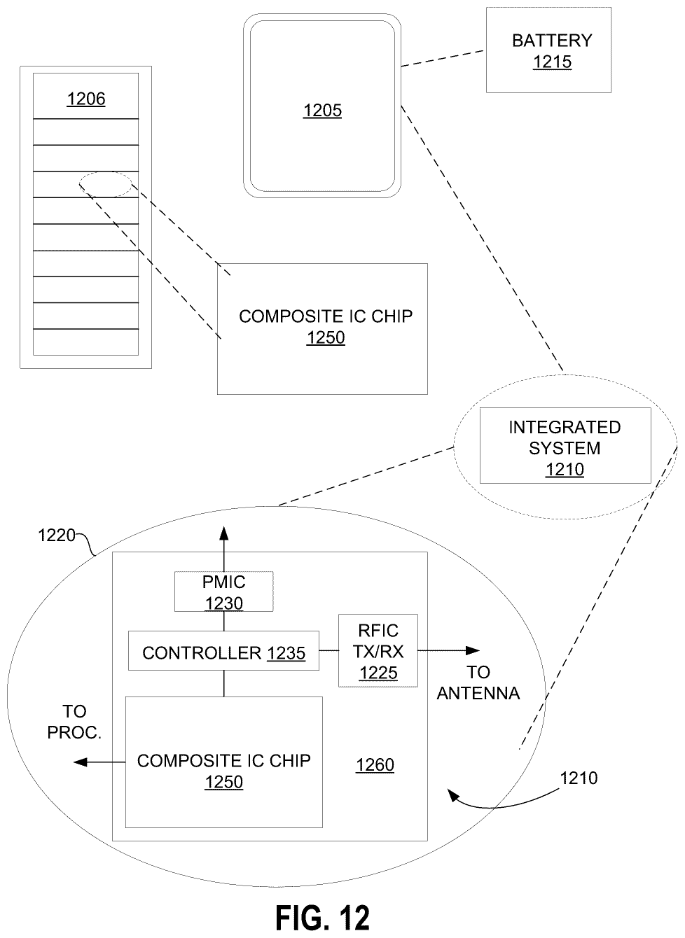

FIG. 12 illustrates a mobile computing platform and a data server machine employing IC die that comprises elevated regions on a surface of a layer of the IC, conductive features on the elevated regions, and a barrier film on sidewalls of the elevated regions, for example as described elsewhere herein. Computing device 1100 may be found inside platform 1205 or server machine 1206, for example. The server machine 1206 may be any commercial server, for example including any number of high-performance computing platforms disposed within a rack and networked together for electronic data processing, which in the exemplary embodiment includes an IC die that comprises: a first layer comprising first and second regions on a first surface of the first layer, the first layer comprising a first dielectric material, wherein the second regions are elevated with respect to the first regions. The IC die further comprises conductive features on the elevated, second regions, and a barrier film on sidewalls of the elevated regions, for example as described elsewhere herein. The mobile computing platform 1205 may be any portable device configured for each of electronic data display, electronic data processing, wireless electronic data transmission, or the like. For example, the mobile computing platform 1205 may be any of a tablet, a smart phone, laptop computer, etc., and may include a display screen (e.g., a capacitive, inductive, resistive, or optical touchscreen), a chip-level or package-level integrated system 1210, and a battery 1215.

Whether disposed within the integrated system 1210 illustrated in the expanded view 1220, or as a stand-alone package within the server machine 1206, an IC package including: a first layer comprising first and second regions on a first surface of the first layer, the first layer comprising a first dielectric material, wherein the second regions are elevated with respect to the first regions. The IC die further comprises conductive features on the elevated, second regions, and a barrier film on sidewalls of the elevated regions, for example as described elsewhere herein. Composite IC chip 1250 may be further coupled to a host substrate 1260, along with, one or more of a power management integrated circuit (PMIC) 1230, RF (wireless) integrated circuit (RFIC) 1225 including a wideband RF (wireless) transmitter and/or receiver (TX/RX) (e.g., including a digital baseband and an analog front-end module further comprises a power amplifier on a transmit path and a low noise amplifier on a receive path), and a controller 1235. PMIC 1230 may perform battery power regulation, DC-to-DC conversion, etc., and so has an input coupled to battery 1215 and with an output providing a current supply to other functional modules. As further illustrated, in the exemplary embodiment, RFIC 1225 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An apparatus comprising: a first layer comprising a first dielectric material, and first and second regions on a first side of the first layer, the first regions comprising a first surface in a first plane, and each of the second regions comprising a second surface in a second plane spaced away from the first plane by a first distance, wherein sidewalls extend between the first surface and the second surfaces; a plurality of conductive features, each conductive feature comprising a bottom surface on one of the second surfaces; and a barrier film comprising a second dielectric material and contacting the sidewalls.

Example 2: The apparatus of example 1, wherein each of the conductive features comprises a top surface opposite the bottom surface, and a conductive feature sidewall extending between the bottom surface and the top surface; and the barrier film contacts the conductive feature sidewall and the top surface of the conductive features.

Example 3: The apparatus of example 1 or example 2, wherein the second dielectric material comprises silicon nitride, silicon oxynitride, silicon oxide, or a carbon doped oxide.

Example 4: The apparatus of any of examples 1 to 3, wherein the first dielectric material comprises composite polymer/filler material, an organic material, or a polyimide.

Example 5: The apparatus of any of examples 1 to 4, wherein the first dielectric material comprises a filler-less material.

Example 6: The apparatus of any of examples 1 to 5, wherein the first surface has a first surface roughness value, the second surface has a second surface roughness value, and the first surface roughness value is greater than the second surface roughness value.

Example 7: The apparatus of any of examples 1 to 6, wherein the first distance is between 25 nanometers and 10 microns.

Example 8: The apparatus of any of examples 1 to 7, wherein the barrier film is on the first surface and has a thickness on the first surface equal to the first distance.

Example 9: The apparatus of any of examples 1 to 7, wherein the barrier film is on the first surface and has a thickness on the first surface less than the first distance.

Example 10: The apparatus of any of examples 1 to 9, further comprising a second layer over the first layer, the second layer comprising: the plurality of conductive features; and a third dielectric material.

Example 11: The apparatus of example 10, further comprising: a third layer over the second layer, wherein the third layer comprises: third and fourth regions on a third side, the third layer comprising the first dielectric material, wherein the third regions comprise a third surface in a third plane, and each of the fourth regions comprise a fourth surface in a fourth plane spaced away from the third plane by a second distance, and second sidewalls extending between the third and fourth surfaces; a plurality of second conductive features, each second conductive feature comprising a bottom surface on one of the fourth surfaces; and a second barrier film comprising the second dielectric material, the second barrier film contacting the second sidewalls.

Example 12: The apparatus of any of examples 1 to 11, wherein the apparatus comprises processor circuitry.

Example 13: A system comprising: a microprocessor comprising circuitry on an integrated circuit (IC) die, wherein the IC die comprises: a first layer comprising a first dielectric material and a first side, the first side comprising first and second regions, wherein the first region comprises a first surface in a first plane, each of the second regions comprise a second surface in a second plane spaced away from the first plane by a first distance, the first side further comprising sidewalls extending between the first and second surfaces; a plurality of conductive features, each conductive feature comprising a bottom surface in contact with one of the second regions; and a barrier film on the first surface between first and second conductive features and comprising a second dielectric material.

Example 14: The system of example 13, wherein the barrier film has a thickness equal to the first distance.

Example 15: The system of example 13 or example 14, wherein the each of the conductive features comprises a top surface opposite the bottom surface, and a conductive feature sidewall extending between the bottom surface and the top surface; and the barrier film contacts the conductive feature sidewalls and the top surface of the conductive features.

Example 16: The system of any of examples 13 to 15, wherein the second dielectric material comprises silicon nitride.

Example 17: The system of any of examples 13 to 16, wherein the first dielectric material comprises composite polymer/filler material, an organic material, or a polyimide.

Example 18: The system of any of examples 13 to 17, wherein the first surface has a first surface roughness value, the second surface has a second surface roughness value, and the first surface roughness value is greater than the second surface roughness value.

Example 19: A method comprising: forming conductive features on a first side of a first layer of an IC die, the first layer comprising a first dielectric material, and first and second regions on the first side, wherein each of the conductive features comprises a bottom surface on a respective one of the second regions; etching the first side to create a first surface in a first plane in the first regions and second surfaces in the second regions, wherein each of the second surfaces are in a second plane spaced away from the first plane by a first distance, and sidewalls extend between the first surface and the second surfaces; and forming a barrier film contacting the sidewalls, the barrier film comprising a second dielectric material.

Example 20: The method of example 19, wherein the second dielectric material comprises silicon nitride, silicon oxynitride, silicon oxide, or a carbon doped oxide.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. An apparatus comprising:
a first layer comprising a first dielectric material, and first and second regions on a first side of the first layer, the first regions comprising a first surface in a first plane, and each of the second regions comprising a second surface in a second plane spaced away from the first plane by a first distance, wherein sidewalls extend between the first surface and the second surfaces;
a plurality of conductive features, each conductive feature comprising a bottom surface on one of the second surfaces; and
a barrier film comprising a second dielectric material and contacting the sidewalls.

2. The apparatus of claim 1, wherein each of the conductive features comprises a top surface opposite the bottom surface, and a conductive feature sidewall extending between the bottom surface and the top surface; and
the barrier film contacts the conductive feature sidewall and the top surface of the conductive features.

3. The apparatus of claim 1, wherein the second dielectric material comprises silicon nitride, silicon oxynitride, silicon oxide, or a carbon doped oxide.

4. The apparatus of claim 1, wherein the first dielectric material comprises composite polymer/filler material, an organic material, or a polyimide.

5. The apparatus of claim 1, wherein the first dielectric material comprises a filler-less material.

6. The apparatus of claim 1, wherein the first surface has a first surface roughness value, the second surface has a second surface roughness value, and the first surface roughness value is greater than the second surface roughness value.

7. The apparatus of claim 1, wherein the first distance is between 25 nanometers and 10 microns.

8. The apparatus of claim 1, wherein the barrier film is on the first surface and has a thickness on the first surface equal to the first distance.

9. The apparatus of claim 1, wherein the barrier film is on the first surface and has a thickness on the first surface less than the first distance.

10. The apparatus of claim 1, further comprising a second layer over the first layer, the second layer comprising:
the plurality of conductive features; and
a third dielectric material.

11. The apparatus of claim 10, further comprising:
a third layer over the second layer, wherein the third layer comprises:
third and fourth regions on a third side, the third layer comprising the first dielectric material, wherein the third regions comprise a third surface in a third plane, and each of the fourth regions comprise a fourth surface in a fourth plane spaced away from the third plane by a second distance, and second sidewalls extending between the third and fourth surfaces;
a plurality of second conductive features, each second conductive feature comprising a bottom surface on one of the fourth surfaces; and
a second barrier film comprising the second dielectric material, the second barrier film contacting the second sidewalls.

12. The apparatus of claim 1, wherein the apparatus comprises processor circuitry.

13. A system comprising:
a microprocessor comprising circuitry on an integrated circuit (IC) die, wherein the IC die comprises:
a first layer comprising a first dielectric material and a first side, the first side comprising first and second regions, wherein the first region comprises a first surface in a first plane, each of the second regions comprise a second surface in a second plane spaced away from the first plane by a first distance, the first side further comprising sidewalls extending between the first and second surfaces;
a plurality of conductive features, each conductive feature comprising a bottom surface in contact with one of the second regions; and
a barrier film on the first surface between first and second conductive features and comprising a second dielectric material.

14. The system of claim 13, wherein the barrier film has a thickness equal to the first distance.

15. The system of claim 13, wherein the each of the conductive features comprises a top surface opposite the bottom surface, and a conductive feature sidewall extending between the bottom surface and the top surface; and
the barrier film contacts the conductive feature sidewalls and the top surface of the conductive features.

16. The system of claim 13, wherein the second dielectric material comprises silicon nitride.

17. The system of claim 13, wherein the first dielectric material comprises composite polymer/filler material, an organic material, or a polyimide.

18. The system of claim 13, wherein the first surface has a first surface roughness value, the second surface has a second surface roughness value, and the first surface roughness value is greater than the second surface roughness value.

19. A method comprising:
forming conductive features on a first side of a first layer of an IC die, the first layer comprising a first dielectric material, and first and second regions on the first side, wherein each of the conductive features comprises a bottom surface on a respective one of the second regions;
etching the first side to create a first surface in a first plane in the first regions and second surfaces in the second regions, wherein each of the second surfaces are in a second plane spaced away from the first plane by a first distance, and sidewalls extend between the first surface and the second surfaces; and
forming a barrier film contacting the sidewalls, the barrier film comprising a second dielectric material.

20. The method of claim 19, wherein the second dielectric material comprises silicon nitride, silicon oxynitride, silicon oxide, or a carbon doped oxide.
